(19) United States
(12) Patent Application Publication
(10) Pub. No.: US 2025/0157975 A1
(43) Pub. Date: May 15, 2025

(54) SEMICONDUCTOR DEVICE AND METHOD FOR PRODUCING SEMICONDUCTOR DEVICE

(71) Applicant: NITTO DENKO CORPORATION, Ibaraki-shi, Osaka (JP)

(72) Inventors: Tsubasa OMURA, Ibaraki-shi, Osaka (JP); Masatoshi KATO, Ibaraki-shi, Osaka (JP); Naofumi KOSAKA, Ibaraki-shi, Osaka (JP); Yuichiro SHISHIDO, Ibaraki-shi, Osaka (JP)

(21) Appl. No.: 18/833,091

(22) PCT Filed: Jan. 13, 2023
(86) PCT No.: PCT/JP2023/000790

§ 371 Date: Jul. 25, 2024

(30) Foreign Application Priority Data
Jan. 31, 2022 (JP) 2022-012743
Jul. 25, 2022 (JP) 2022-118203

(51) Int. Cl. H01L 23/00; H01L 25/07

(52) U.S. Cl. CPC H01L 24/29; H01L 24/16; H01L 24/32; H01L 24/73; H01L 24/81; H01L 24/83; H01L 24/92; H01L 25/074; H01L 2224/16146; H01L 2224/2929; H01L 2224/32145; H01L 2224/73204; H01L 2224/81101; H01L 2224/81815; H01L 2224/83005; H01L 2224/83191; H01L 2224/83862; H01L 2224/9201; H01L 2224/92143; H01L 2225/06541

(57) ABSTRACT

A semiconductor device is a semiconductor substrate including a through electrode passing through in a thickness direction, and includes the plurality of semiconductor substrates disposed in the thickness direction and a curing resin layer disposed between the semiconductor substrates adjacent to each other in the thickness direction. The curing resin layer includes a curing resin and a columnar solder portion embedded in the curing resin. The columnar solder portion passes through the curing resin so as to electrically connect the through electrodes of the semiconductor substrates adjacent to each other in the thickness direction.

### TECHNICAL FIELD

The present invention relates to a semiconductor device and a method for producing a semiconductor device.

### BACKGROUND ART

Recently, from the viewpoint of achieving a large capacity and high-speed communication of electronic devices, DRAM (Dynamic Random Access Memory) has been used.

The DRAM consists of a plurality of laminated semiconductor elements (semiconductor substrates including the semiconductor elements). As a method for laminating the plurality of semiconductor elements (semiconductor substrates including the semiconductor elements), for example, a TSV (Through Silicon Via) method has been known. In the TSV method, the semiconductor elements (semiconductor substrates including the semiconductor elements) are drilled and filled with a metal, and the semiconductor elements are electrically connected to each other.

On the other hand, in the TSV method, from the viewpoint of improvement of reliability, the semiconductor element is sealed with a resin. As a method for sealing the semiconductor element with the resin, for example, a method in which an underfill material fills a gap between the substrate and a semiconductor chip, and the semiconductor chip is sealed has been proposed (ref: for example, Patent Document 1).

### CITATION LIST

Patent Document
Patent Document 1: Japanese Unexamined Patent Publication No. 2000-260820

### SUMMARY OF THE INVENTION

### Problem to be Solved by the Invention

On the other hand, it is required to further more reduce a height of the DRAM. When the height of the DRAM is reduced, the gap between the semiconductor substrates becomes small. Then, the underfill material of Patent Document 1 cannot sufficiently fill the gap. As a result, there is a problem that the reliability of the semiconductor device is reduced.

The present invention provides a semiconductor device having excellent reliability, and a method for producing a semiconductor device for producing the semiconductor device having the excellent reliability.

### Means for Solving the Problem

The present invention [1] includes a semiconductor device including a plurality of semiconductor substrates disposed in a thickness direction each including a through electrode passing through in the thickness direction, and a curing resin layer disposed between the semiconductor substrates adjacent to each other in the thickness direction, wherein the curing resin layer includes a curing resin and a columnar solder portion embedded in the curing resin, and the columnar solder portion passes through the curing resin so as to electrically connect the through electrodes of the semiconductor substrates adjacent to each other in the thickness direction.

The present invention [2] includes a method for producing a semiconductor device including a first step of preparing a semiconductor substrate including a through electrode passing through in a thickness direction; a second step of preparing an anisotropic electrically conductive adhesive film including a solder particle and a curable resin; a third step of producing a first laminate by attaching the anisotropic electrically conductive adhesive film on a surface of the semiconductor substrate; a fourth step of producing a second laminate by laminating the plurality of first laminates; a fifth step of forming a columnar solder portion so as to electrically connect the through electrodes of the semiconductor substrates adjacent to each other in the thickness direction by heating the second laminate and melting the solder particle; and a sixth step of heating the second laminate and curing the curable resin.

The present invention [3] includes the method for producing a semiconductor device described in the above-described [2], wherein after the third step and before the fourth step, a seventh step of singulating the first laminates is provided, and in the fourth step, the plurality of singulated first laminates are laminated to produce a second laminate.

The present invention [4] includes the method for producing a semiconductor device described in the above-described [3], wherein the seventh step includes a step of preparing a dicing tape extendable in a plane direction perpendicular to the thickness direction, a step of disposing the first laminate on one surface in the thickness direction of the dicing tape, and a step of singulating the first laminate by extending the dicing tape in the plane direction.

The present invention [5] includes the method for producing a semiconductor device described in the above-described [3], wherein in the first step, the semiconductor substrate is disposed on a dicing tape extendable in a plane direction perpendicular to the thickness direction.

The present invention [6] includes the method for producing a semiconductor device described in the above-described [3], wherein in the second step, the anisotropic electrically conductive adhesive film is disposed on a dicing tape extendable in a plane direction perpendicular to the thickness direction.

The present invention [7] includes the method for producing a semiconductor device described in any one of the above-described [2] to [6], wherein in the fourth step, by laminating the first laminate with heating below 100° C., the second laminate is produced, or by laminating the first laminate without heating, the second laminate is produced, and in the fifth step, the second laminate consisting of the plurality of first laminates is collectively heated.

The present invention [8] includes the method for producing a semiconductor device described in the above-described [7], wherein in the fourth step, by laminating the first laminate without heating, the second laminate is produced, and in the fifth step, the second laminate consisting of the plurality of first laminates is collectively heated.

The present invention [9] includes the method for producing a semiconductor device described in any one of the above-described [2] to [8], wherein in the fifth step, the heating is carried out so that the maximum temperature is higher than a softening point of the curable resin.

The present invention includes the method for producing a semiconductor device described in the above-described [9], wherein the maximum temperature is 150° C. or more and 260° C. or less.

The present invention includes the method for producing a semiconductor device described in any one of the above-described [2] to [10], wherein in the fifth step, the heating is carried out in a pressure oven.

The present invention includes the method for producing a semiconductor device described in any one of the above-described [2] to [11], wherein in the sixth step, the heating is carried out so that the maximum temperature is 100° C. or more and 260° C. or less.

The present invention includes the method for producing a semiconductor device described in any one of the above-described [2] to [12], wherein the heating in the sixth step is carried out in a pressure oven.

### Effect of the Invention

The semiconductor device of the present invention includes the curing resin layer disposed between the semiconductor substrates adjacent to each other in the thickness direction. Therefore, it is possible to reliably seal the semiconductor element in the semiconductor substrate. As a result, reliability is excellent. Further, in the semiconductor device, the columnar solder portion passes through the curing resin so as to electrically connect the through electrodes of the semiconductor substrates adjacent to each other in the thickness direction. Therefore, it is possible to reliably electrically connect the through electrodes to each other.

In the method for producing a semiconductor device of the present invention, the anisotropic electrically conductive adhesive film is attached to one surface in the thickness direction of the semiconductor substrate, thereby producing the first laminate, and thereafter, the plurality of first laminates are laminated, thereby producing the second laminate. Thereafter, the curable resin in the anisotropic electrically conductive adhesive film is cured. That is, in this method, only by attaching the anisotropic electrically conductive adhesive film, and then, by curing, it is possible to seal the semiconductor element. Therefore, it is possible to produce the semiconductor device having excellent reliability.

Further, in the method for producing a semiconductor device, by heating the second laminate and melting the solder particle, a columnar solder portion 7 is formed so as to electrically connect the through electrodes of the semiconductor substrates adjacent to each other in the thickness direction. That is, only by attaching the anisotropic electrically conductive adhesive film and then, by heating, it is possible to electrically connect the through electrodes to each other. Therefore, it has excellent productivity.

### BRIEF DESCRIPTION OF THE DRAWINGS

FIG. 1 shows a first step of preparing a semiconductor substrate.

FIG. 2 shows a second step of preparing an anisotropic electrically conductive adhesive film.

FIG. 3 shows a third step of producing a first laminate by attaching an anisotropic electrically conductive adhesive film onto a surface (one surface in a thickness direction) of a semiconductor substrate.

FIGS. 4A to 4C show steps of preparing a plurality of first laminates 5 in a fourth step:

FIG. 4A illustrating a step of preparing a dicing tape, a step of disposing the first laminate on one surface in a thickness direction of the dicing tape, and a step of forming a fragile portion in a first laminate 5;

FIG. 4B illustrating a step of singulating the first laminates by extending the dicing tape in a plane direction; and

FIG. 4C illustrating a step of peeling the plurality of first laminates (singulated first laminates) from the dicing tape, and picking up the singulated first laminates.

FIG. 5 shows a fourth step of producing a second laminate by laminating the plurality of first laminates.

FIG. 6 shows a fifth step of forming a columnar solder portion so as to electrically connect through electrodes of semiconductor substrates adjacent to each other in a thickness direction by heating the second laminate and melting solder particles.

FIG. 7 shows a sixth step of heating a second laminate and curing a curable resin.

FIGS. 8A and 8B show modified examples of disposing an anisotropic electrically conductive adhesive film on a dicing tape in a second step:

FIG. 8A illustrating a second step of disposing the anisotropic electrically conductive adhesive film on one surface in a thickness direction of the dicing tape and

FIG. 8B illustrating a third step of producing a first laminate by attaching the anisotropic electrically conductive adhesive film to the surface (other surface in the thickness direction) of the semiconductor substrate.

FIG. 9 shows an explanatory view for illustrating a void ratio in evaluation of sealing properties.

### DESCRIPTION OF EMBODIMENTS

### <Method for Producing Semiconductor Device>

A method for producing a semiconductor device of the present invention includes a first step of preparing a semiconductor substrate including a through electrode passing through in a thickness direction; a second step of preparing an anisotropic electrically conductive adhesive film including a solder particle and a curable resin; a third step of producing a first laminate by attaching the anisotropic electrically conductive adhesive film onto a surface (one surface in the thickness direction) of the semiconductor substrate; a fourth step of producing a second laminate by laminating the plurality of first laminates; a fifth step of forming a columnar solder portion so as to electrically connect the through electrodes of the semiconductor substrates adjacent to each other in the thickness direction by heating the second laminate and melting the solder particle; and a sixth step of heating the second laminate and curing the curable resin.

One embodiment of the method for producing a semiconductor device of the present invention is described in detail below.

### First Step

In the first step, as shown in FIG. 1, a semiconductor substrate 1 is prepared.

The semiconductor substrate 1 has a predetermined thickness, and has a flat plate shape. The semiconductor substrate 1 has a flat upper surface 31 and a flat lower surface 32. A plurality of semiconductor elements (not shown) are provided on the upper surface 31.

The semiconductor substrate 1 includes a through electrode 2 passing through in the thickness direction.

The through electrode 2 is formed so as to pass through from the upper surface 31 of the semiconductor substrate 1 toward the lower surface 32. The through electrode 2 is electrically connected for each semiconductor element. The plurality of through electrodes 2 are disposed spaced from each other in the semiconductor substrate 1, and an interval therebetween is, for example, 1 μm or more, preferably 10 μm or more, and for example, 20 μm or less.

A thickness of the semiconductor substrate 1 is, for example, 20 μm or more, and for example, 1000 μm or less.

### Second Step

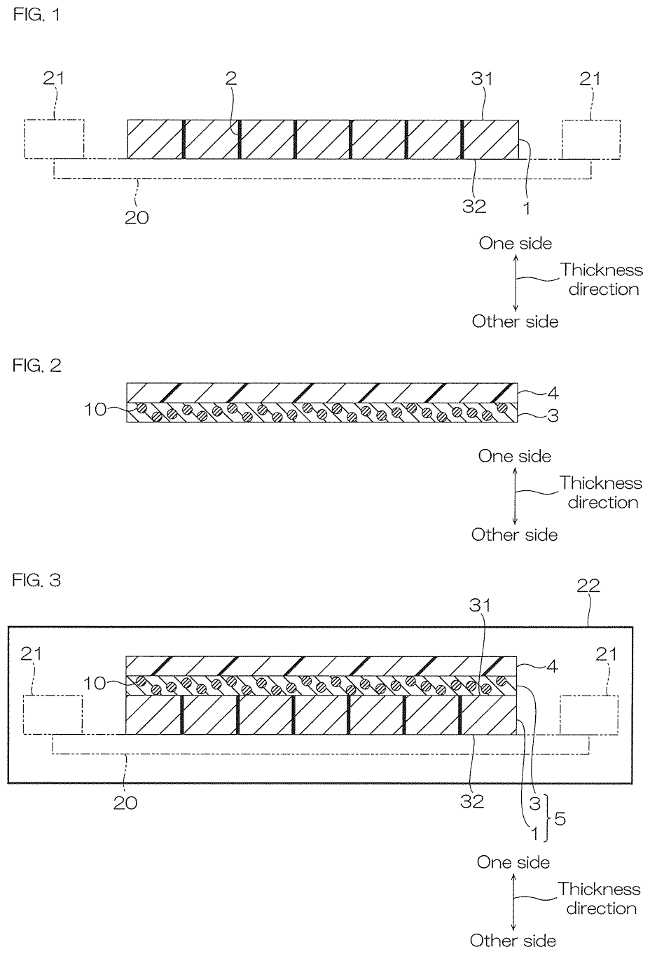

In the second step, as shown in FIG. 2, an anisotropic electrically conductive adhesive film 3 is prepared.

To prepare the anisotropic electrically conductive adhesive film 3, first, an anisotropic electrically conductive adhesive film composition is prepared.

The anisotropic electrically conductive adhesive film composition contains solder particles 10 and a curable resin.

Examples of a solder material for forming the solder particles 10 include solder materials which do not contain lead (lead-free solder material) from the viewpoint of environmental adequacy. Specifically, examples of the solder material include tin and tin alloys. Examples of the tin alloy include tin-bismuth alloys (Sn—Bi), tin-silver-copper alloys (Sn—Ag—Cu), and tin-silver alloys (Sn—Ag).

A content ratio of the tin in the tin-bismuth alloy is, for example, 10% by mass or more, preferably 25% by mass or more, and for example, 50% by mass or less, preferably 45% by mass. Further, the content ratio of the bismuth in the tin-bismuth alloy is, for example, 50% by mass or more, preferably, 55% by mass or more, and for example, 90% by mass or less, preferably 75% by mass or less.

Further, the content ratio of the tin in the tin-silver-copper alloy is, for example, 90% by mass or more, preferably 95% by mass or more. Further, the content ratio of the silver in the tin-silver-copper alloy is, for example, 10% by mass or less, preferably 5% by mass or less. Further, the content ratio of the copper in the tin-silver-copper alloy is, for example, 1% by mass or less, preferably 0.5% by mass or less.

Further, the content ratio of the tin in the tin-silver alloy is, for example, 90% by mass or more, preferably 95% by mass or more. Further, the content ratio of the silver in the tin-silver alloy is, for example, 10% by mass or less, preferably 5% by mass or less.

A melting point of the solder material (that is, the melting point of the solder particle 10) is, for example, 260° C. or less, preferably 235° C. or less, and for example, 100° C. or more, preferably 130° C. or more. The melting point is determined by differential scanning calorimetry (DSC) (hereinafter, the same applies).

A shape of the solder particle 10 is not particularly limited, and examples thereof include spherical shapes, plate shapes, and needle shapes. As the shape of the solder particle 10, preferably, a spherical shape is used. In FIG. 2, though the shape of the solder particle 10 is shown as the spherical shape, the shape of the solder particle 10 is not limited to this.

An average value of the maximum length of the solder particle 10 (in the case of the spherical shape, an average particle size) is, for example, 50 μm or less, preferably 40 μm or less, more preferably 10 μm or less. The average value of the maximum length is measured using a laser diffraction scattering particle size distribution meter.

The surface of the solder particle 10 is generally coated with an oxide film consisting of an oxide of the solder material. The thickness of the oxide film is, for example, 1 nm or more, and for example, 20 nm or less.

The content ratio of the solder particles 10 is, for example, 10% by volume or more, preferably 15% by volume or more, and for example, 50% by volume or less, preferably 40% by volume or less with respect to the anisotropic electrically conductive adhesive film composition. Further, the content ratio of the solder particles 10 is, for example, 30 parts by mass or more, and for example, 80 parts by mass or less, preferably 75 parts by mass or less with respect to 100 parts by mass of the total amount of the solder particles 10 and the curable resin.

These solder particles 10 may be used alone or in combination of two or more.

Examples of the curable resin include thermosetting resins. Examples of the thermosetting resin include epoxy resins (for example, bisphenol A-type epoxy resins), urea resins, melamine resins, diallyl phthalate resins, silicone resins, phenol resins, thermosetting acrylic resins, thermosetting polyesters, thermosetting polyimides, and thermosetting polyurethanes.

A softening point of the curable resin is, for example, 50° C. or more, preferably 80° C. or more, and for example, 230° C. or less, preferably 200° C. or less. The softening point can be measured with a thermomechanical analyzer.

The content ratio of the curable resin is, for example, 10% by volume or more, preferably 20% by volume or more, and for example, 90% by volume or less, preferably 85% by volume or less with respect to the anisotropic electrically conductive adhesive film composition. Further, the content ratio of the curable resin is, for example, 20 parts by mass or more, preferably 25 parts by mass or more, and for example, 70 parts by mass or less with respect to 100 parts by mass of the total amount of the solder particles 10 and the curable resin.

These curable resins may be used alone or in combination of two or more.

The anisotropic electrically conductive adhesive film composition may also contain a thermoplastic resin as needed.

The thermoplastic resin is blended so as to reliably form the anisotropic electrically conductive adhesive film composition into a sheet. Examples of the thermoplastic resin include phenoxy resins, polyolefins (for example, polyethylene, polypropylene, ethylene-propylene copolymers, or the like), acrylic resins, polyesters, polyvinyl acetate, ethylene-vinyl acetate copolymers, polyvinyl chloride, polystyrene, polyacrylonitrile, polyamide (nylon (registered trademark)), polycarbonate, polyacetal, polyethylene terephthalate, polyphenylene oxide, polyphenylene sulfide, polysulfone, polyether sulfone, polyether ether ketone, polyallyl sulfone, thermoplastic polyimide, thermoplastic polyurethane, polyaminobismaleimide, polyamide imide, polyether imide, bismaleimide triazine resins, polymethylpentene, fluoride resins, liquid crystal polymers, olefin-vinyl alcohol copolymers, ionomers, polyarylates, acrylonitrile-ethylene-styrene copolymers, acrylonitrile-butadiene-styrene copolymers, acrylonitrile-styrene copolymers, and butadiene-styrene copolymers.

The content ratio of the thermoplastic resin is, for example, 5% by volume or more, preferably 10% by volume or more, and for example, 80% by volume or less, preferably 70% by volume or less with respect to the anisotropic electrically conductive adhesive film composition.

These thermoplastic resins may be used alone or in combination of two or more.

Further, the anisotropic electrically conductive adhesive film compositions may contain flux as needed.

The flux is a component for removing the oxide film (oxide film consisting of the oxide of the solder material) on the surfaces of the solder particles 10.

Examples of the material for the flux include organic acid salts. Examples of the organic acid salt include organic acids, quinolinol derivatives, and metal carbonyl acid salts. Examples of the organic acid include aliphatic carboxylic acids and aromatic carboxylic acids. Examples of the aliphatic carboxylic acid include aliphatic dicarboxylic acids. Specific examples of the aliphatic dicarboxylic acid include adipic acid, malic acid, malonic acid, succinic acid, glutaric acid, pimelic acid, suberic acid, and sebacic acid. Examples of the aromatic carboxylic acid include benzoic acid, 2-phenoxybenzoic acid, phthalic acid, diphenylacetic acid, trimellitic acid, and pyromellitic acid. As the material for the flux, preferably, an organic acid is used. As the material for the flux, more preferably, an aliphatic carboxylic acid is used. As the material for the flux, further more preferably, a malic acid is used.

The melting point of the flux is, for example, 200° C. or less, preferably 180° C. or less, more preferably 160° C. or less, and for example, 100° C. or more, preferably 120° C. or more, more preferably 130° C. or more.

The shape of the flux is not particularly limited, and examples thereof include plate shapes, needle shapes, and spherical shapes. Further, the flux may be also dissolved in a known solvent.

The content ratio of the flux is, for example, 0.1% by volume or more, preferably 1% by volume or more, and also, for example, 50% by volume or less, preferably 20% by volume or less with respect to the anisotropic electrically conductive adhesive film composition. Also, the content ratio of the flux is, for example, 1 part by mass or more, and for example, 20 parts by mass or less with respect to 100 parts by mass of the solder particles 10.

The flux may be used alone or in combination of two or more.

Further, the anisotropic electrically conductive adhesive film composition may also contain an additive (for example, a curing agent, a curing accelerator, and a silane coupling agent) as needed.

Then, in order to prepare the anisotropic electrically conductive adhesive film composition, the solder particles 10, the curable resin, the thermoplastic resin to be blended as needed, the flux to be blended as needed, and the additive to be blended as needed are mixed. Thus, the anisotropic electrically conductive adhesive film composition is prepared. Further, the anisotropic electrically conductive adhesive film composition may be also blended into the known solvent, so that the anisotropic electrically conductive adhesive film composition may be prepared as a varnish.

Next, in order to prepare the anisotropic electrically conductive adhesive film 3, the anisotropic electrically conductive adhesive film composition (varnish of the anisotropic electrically conductive adhesive film composition) is coated onto the other surface in the thickness direction of a release liner 4, and is dried as needed.

The release liner 4 is a film for covering and protecting the anisotropic electrically conductive adhesive film 3. The release liner 4 has a film shape.

The release liner 4 is, for example, a plastic substrate (plastic film). Examples of the plastic substrate include polyester sheets (polyethylene terephthalate (PET) sheet), polyolefin sheets (for example, a polyethylene sheet, a polypropylene sheet), polyvinyl chloride sheets, polyimide sheets, and polyamide sheets (nylon sheet). The surface (other surface in the thickness direction) of the release liner 4 may be also subjected to a surface treatment such as silicone treatment.

The thickness of the release liner 4 is, for example, 1 μm or more, and for example, 100 μm or less.

Thus, the anisotropic electrically conductive adhesive film 3 is prepared on the other surface in the thickness direction of the release liner 4.

As drying conditions, a drying temperature is, for example, 20° C. or more, preferably 40° C. or more, and for example, 90° C. or less, preferably 70° C. or less. Drying time is, for example, 10 seconds or more, preferably 3 minutes or more, and for example, 120 minutes or less, preferably 60 minutes or less, more preferably 10 minutes or less.

Such an anisotropic electrically conductive adhesive film 3 has a film shape (including a sheet shape) having a predetermined thickness.

The anisotropic electrically conductive adhesive film 3 is formed from the anisotropic electrically conductive adhesive film composition including the solder particles 10 and the curable resin. Therefore, the anisotropic electrically conductive adhesive film 3 contains the solder particles 10 and the curable resin. Specifically, the anisotropic electrically conductive adhesive film 3 contains the curable resin and the solder particles 10 dispersed in the curable resin.

The thickness of the anisotropic electrically conductive adhesive film 3 is, for example, 1 μm or more, and for example, 30 μm or less.

### Third Step

In the third step, as shown in FIG. 3, the anisotropic electrically conductive adhesive film 3 is attached to the surface (one surface in the thickness direction) of the semiconductor substrate 1, thereby producing a first laminate 5.

Specifically, one surface in the thickness direction of the semiconductor substrate 1 and the other surface in the thickness direction of the anisotropic electrically conductive adhesive film 3 are disposed to face each other to be put into a vacuum chamber 22 including a vacuum press machine (not shown). Next, the vacuum chamber 22 is decompressed. Specifically, the vacuum chamber 22 is evacuated with a vacuum pump (decompression pump) or the like. Thereafter, the other surface in the thickness direction of the anisotropic electrically conductive adhesive film 3 is compressively bonded to one surface in the thickness direction of the semiconductor substrate 1 with the vacuum press machine (not shown), while the vacuum chamber 22 is brought into a reduced pressure atmosphere. The reduced pressure atmosphere is, for example, 1000 Pa or less, preferably 100 Pa or less. Thus, the anisotropic electrically conductive adhesive film 3 is attached to one surface in the thickness direction of the semiconductor substrate 1, thereby producing the first laminate 5. Thereafter, the first laminate 5 is released under an atmospheric pressure atmosphere. Thereafter, the release liner 4 is peeled from the first laminate 5.

### Fourth Step

In the fourth step, the plurality of first laminates 5 are laminated, thereby producing a second laminate 6.

In order to laminate the plurality of first laminates 5, first, the plurality of first laminates 5 are prepared.

In order to prepare the plurality of first laminates 5, the first laminates 5 are singulated. That is, in this method, after the third step and before the fourth step, the seventh step of singulating the first laminates 5 is provided.

The seventh step includes a step of preparing a dicing tape 20 extendable in a plane direction perpendicular to the thickness direction (7A step), a step of disposing the first laminate 5 on one surface in the thickness direction of the dicing tape 20 (7B step), a step of forming a fragile portion in the first laminate 5 (7C step), a step of singulating the first laminates 5 by extending the dicing tape 20 in the plane direction (7D step), and a step of peeling a plurality of singulated first laminates 5′ from the dicing tape 20 to pick up the singulated first laminates 5′ (7E step).

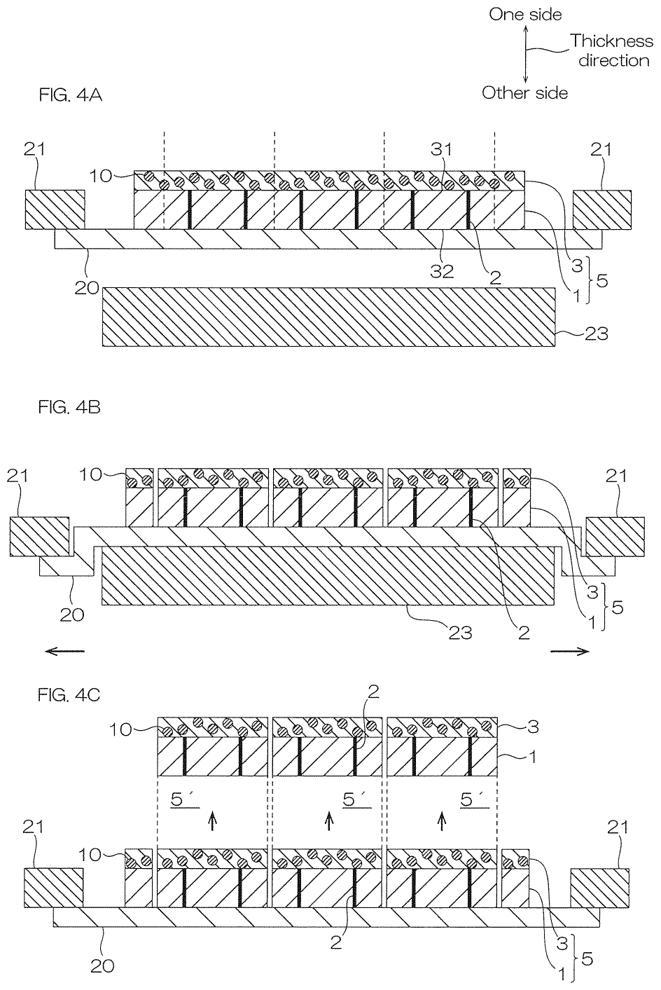

In the 7A step, as shown in FIG. 4A, the dicing tape 20 is prepared.

The dicing tape 20 is a film extendable in the plane direction perpendicular to the thickness direction. The dicing tape 20 has a flat plate shape having a size corresponding to the semiconductor substrate 1.

The dicing tape 20 includes a substrate (not shown) and a pressure-sensitive adhesive layer (not shown) disposed on the surface of the substrate (not shown).

Further, a ring frame 21 is attached to a peripheral end region of a pressure-sensitive adhesive layer (not shown) of the dicing tape 20. The ring frame 21 is a holder for holding the dicing tape 20 in a chuck table 23 to be described later.

In the 7B step, as shown in FIG. 4A, the first laminate 5 is disposed on one surface in the thickness direction of the dicing tape 20.

In order to dispose the first laminate 5 on one surface in the thickness direction of the dicing tape 20, one surface in the thickness direction (pressure-sensitive adhesive layer (not shown)) of the dicing tape 20 and the other surface in the thickness direction of the first laminate 5 (the lower surface 32 of the semiconductor substrate 1) are attached to each other.

In the 7C step, the fragile portion is formed in the first laminate 5.

Specifically, by irradiating a laser to the first laminate 5, the fragile portion is formed along the thickness direction of the first laminate 5 (ref: broken line of FIG. 4A). The fragile portion is formed in a grid shape so as to divide the semiconductor substrate 1 for each semiconductor element.

The fragile portion is a layer having weak strength as compared with another portion in the first laminate 5 (the semiconductor substrate 1 and the anisotropic electrically conductive adhesive film 3). Since the fragile portion is a portion having the weak strength, in the 7D step to be described later, the first laminate 5 can be singulated with the fragile portion as a starting point. Examples of a shape of the fragile portion include slits, perforated lines, and half-cuts.

In the 7D step, the dicing tape 20 is extended in the plane direction, thereby singulating the first laminates 5.

Specifically, as shown in FIG. 4B, the dicing tape 20 (the dicing tape 20 including the first laminate 5 on one surface in the thickness direction) is disposed on one surface in the thickness direction of the chuck table 23 provided in an expanded device, and fixed to the holder (not shown) provided in the chuck table 23 via the ring frame 21.

The chuck table 23 is configured to be movable up and down, to have the upper surface having a plurality of suction ports (not shown) each having an opening, and to be applicable of negative pressure through the suction ports (that is, suction).

Next, as shown in FIG. 4B, the chuck table 23 is raised so as to be brought into contact with the dicing tape 20 from the other surface in the thickness direction. Thus, the dicing tape 20 is expanded in a planar direction and a peripheral direction thereof. Thus, in the first laminate 5, the first laminates 5 are singulated with the fragile portion as the starting point.

In the 7E step, as shown in FIG. 4C, the plurality of singulated first laminates 5′ are peeled from the dicing tape 20, and the singulated first laminates 5′ are picked up. Thus, the plurality of first laminates 5 (the singulated first laminates 5′) are prepared.

Then, in the fourth step, as shown in FIG. 5, the plurality of first laminates 5 (the singulated first laminates 5′) are laminated, thereby producing the second laminate 6.

Specifically, the plurality of first laminates 5 (the singulated first laminates 5′) are disposed on one surface in the thickness direction of a substrate 24 so that the anisotropic electrically conductive adhesive film 3 in the first laminate 5 (the singulated first laminates 5′) is in contact with one surface in the thickness direction of the substrate 24.

The substrate 24 is a substrate of a semiconductor having a size corresponding to the first laminate 5 (the singulated first laminates 5′). The plurality of semiconductor elements (not shown) are provided on one surface in the thickness direction of the substrate 24.

### Fifth Step

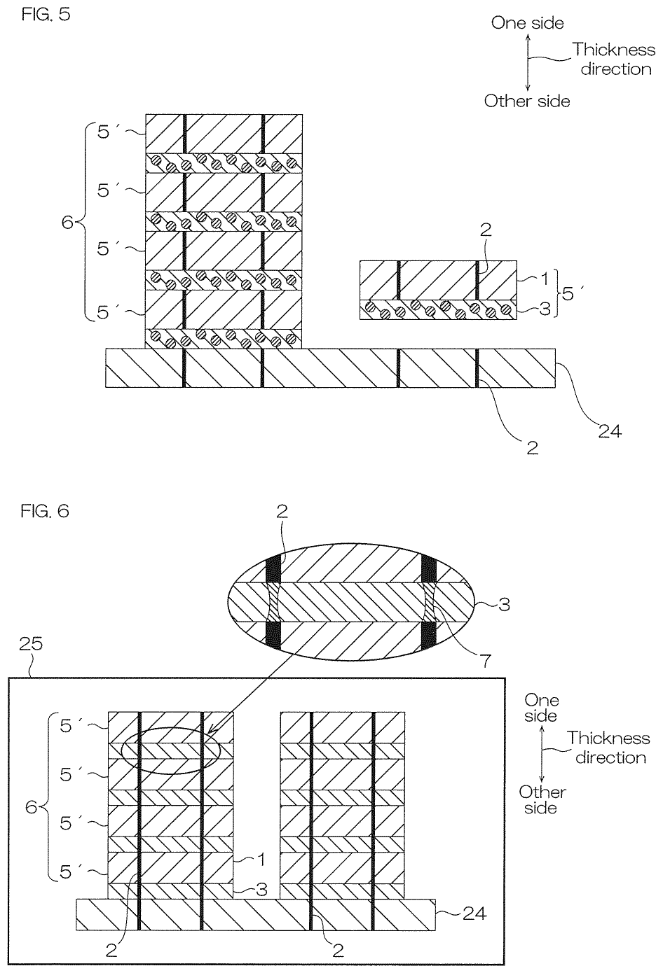

In the fifth step, as shown in FIG. 6, by heating the second laminate 6 and melting the solder particles 10, the columnar solder portion 7 is formed so as to electrically connect the through electrodes 2 of the semiconductor substrates 1 adjacent to each other in the thickness direction.

Specifically, in the fifth step, first, the second laminate 6 is disposed in a pressure oven 25 to be heated. The pressure oven 25 is a generic name of a device capable of being pressurized, while heated in a sealed space, and examples thereof include automatic heating and pressurizing processing devices, pressurizing ovens, void-less pressurizing ovens, autoclaves, and vacuum pressurizing reflow devices.

When the second laminate 6 is heated, volatiles may volatilize by heating. Such volatiles may inhibit electrical connections in the second laminate 6. On the other hand, when the second laminate 6 is heated using the pressure oven 25, it is possible to suppress a generation of the above-described volatiles by pressurization. As a result, it is possible to suppress the above-described inhibition.

A heating temperature is a melting point temperature of the solder particles 10 or more.

The maximum temperature of the heating temperature in the fifth step is preferably set to be higher than a softening point of the curable resin.

When the maximum temperature is set to be higher than the softening point of the curable resin, it is possible to efficiently flow the solder particles 10, thereby forming the columnar solder portion 7.

Also, the maximum temperature of the heating temperature in the fifth step may be preferably higher or lower than the maximum temperature of the heating temperature in the sixth step to be described later. Specifically, the maximum temperature is, for example, 150° C. or more, and for example, 260° C. or less.

The minimum temperature of the heating temperature in the fifth step is, for example, 100° C. or more, preferably 120° C. or more.

Further, a temperature rising rate in the fifth step is preferably faster than or the same as the temperature rising rate in the heating of the sixth step to be described later.

When the temperature rising rate is faster than or the same as the temperature rising rate in the heating of the sixth step to be described later, in the fifth step, it is possible to self-aggregate (described later) the solder particles 10 before the curing of the curable resin starts (before the completion).

The temperature rising rate is, for example, 3° C./min or more, preferably 10° C./min or more, more preferably 20° C./min or more.

Also, the pressure during the heating is, for example, 0.2 MPa or more, and for example, 1.0 MPa or less. The heating time is, for example, 1 minute or more, and for example, 30 minutes or less, preferably 10 minutes or less.

Then, the solder particles 10 are melted by the above-described heating. As shown in an enlarged view of FIG. 6, the melted solder particles 10 aggregate (self-aggregate) between the through electrodes 2 of the semiconductor substrates 1 adjacent to each other in the thickness direction, thereby forming the columnar solder portion 7. On the other hand, the curable resin in the anisotropic electrically conductive adhesive film 3 is forced out by the self-aggregating solder particles 10, and moves to the periphery of the columnar solder portion 7. As the details are described later, such a curable resin is cured by heating in the sixth step.

As described above, most of the melted solder particles 10 are used for the formation of the columnar solder portion 7, and there is a case where a portion of the melted solder particles 10 and/or the non-melted solder particles 10 are not used for the formation of the columnar solder portion 7, and remain dispersed in the curable resin. In this case, a curing resin layer 8 (described later) includes a portion of the melted solder particles 10 and/or the non-melted solder particles 10.

### Sixth Step

In the sixth step, the second laminate 6 is heated, thereby curing the curable resin.

Specifically, the second laminate 6 is disposed in the pressure oven 25 to be heated, thereby curing the curable resin.

As described above, when the second laminate 6 is heated, the volatiles may volatilize by heating. Such volatiles may inhibit the electrical connection in the second laminate 6. On the other hand, when the second laminate 6 is heated using the pressure oven 25, it is possible to suppress the generation of the above-described volatiles by the pressurization. As a result, it is possible to suppress the above-described inhibition.

The maximum temperature of the heating temperature in the sixth step is, for example, 100° C. or more, preferably 150° C. or more, and for example, 260° C. or less.

When the maximum temperature is within the above-described range, it is possible to reliably cure the curable resin.

The minimum temperature of the heating temperature in the sixth step is, for example, 80° C. or more, preferably 90° C. or more.

The temperature rising rate is, from the viewpoint of curability of the curable resin, for example, 3° C./min or more, preferably 10° C./min or more, more preferably 20° C./min or more.

Also, the pressure during the heating is, for example, 0.2 MPa or more, and for example, 1.0 MPa or less. The heating time is, for example, above 30 minutes, preferably 50 minutes or more, and for example, 150 minutes or less, preferably 90 minutes or less.

Then, by the above-described heating, the curable resin is cured to become the curing resin layer 8. In the curing resin layer 8, the columnar solder portion 7 is embedded in a curing resin. Further, the columnar solder portion 7 passes through the curing resin so as to electrically connect the through electrodes 2 of the semiconductor substrates 1 adjacent to each other in the thickness direction.

As described above, a semiconductor device 9 is produced.

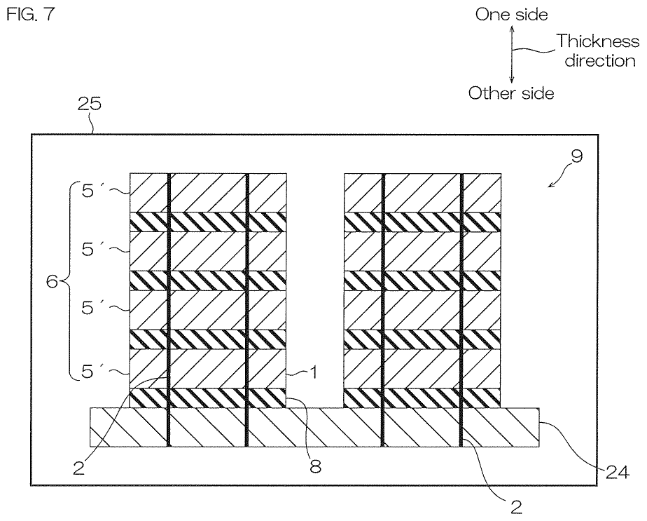

As shown in FIG. 7, the semiconductor device 9 includes the plurality of semiconductor substrates 1 disposed in the thickness direction, and the curing resin layer 8 disposed between the semiconductor substrates 1 adjacent to each other in the thickness direction. Further, the curing resin layer 8 includes the curing resin and the columnar solder portion 7 embedded in the curing resin. Further, the columnar solder portion 7 passes through the curing resin so as to electrically connect the through electrodes 2 of the semiconductor substrates 1 adjacent to each other in the thickness direction.

Also, in the curing resin layer 8, a portion of the melted solder particles 10 and/or the non-melted solder particles 10 which are not used for the formation of the columnar solder portion 7 remain dispersed in the curing resin layer 8.

### Function and Effect

In the method for producing the semiconductor device 9, the anisotropic electrically conductive adhesive film 3 is attached to one surface in the thickness direction of the semiconductor substrate 1, thereby producing the first laminate 5. Thereafter, the plurality of first laminates 5 are laminated, thereby producing the second laminate 6. Thereafter, the curable resin in the anisotropic electrically conductive adhesive film 3 is cured. That is, in this method, only by attaching the anisotropic electrically conductive adhesive film 3, and then, by curing, it is possible to seal the semiconductor element. Therefore, it is possible to produce the semiconductor device 9 having excellent reliability.

Then, according to the method for producing the semiconductor device 9, in particular, even when a reduction in a height of the semiconductor device 9 is achieved, it is possible to produce the semiconductor device 9 having the excellent reliability.

Specifically, according to the method for sealing the semiconductor element described in Patent Document 1, an underfill material fills a gap between the substrate and the semiconductor chip, thereby sealing the semiconductor chip.

On the other hand, when the reduction in the height of the semiconductor device 9 is achieved, in the semiconductor device 9 in which the plurality of semiconductor substrates 1 including the semiconductor elements are laminated, the gap between the semiconductor substrates 1 is reduced. Then, in the underfill material of Patent Document 1, it is not possible to sufficiently fill the gap. As a result, there is a problem that the reliability of the semiconductor device 9 is reduced.

On the other hand, according to the method for producing the semiconductor device 9, only by attaching the anisotropic electrically conductive adhesive film 3, and then, by curing, it is possible to seal the semiconductor element. Therefore, even when the above-described gap is narrow, it is possible to reliably seal the semiconductor element. As a result, it is possible to produce the semiconductor device 9 having the excellent reliability.

Further, in the method for producing the semiconductor device 9, by heating the second laminate 6 and melting the solder particles 10, the columnar solder portion 7 is formed so as to electrically connect the through electrodes 2 of the semiconductor substrates 1 adjacent to each other in the thickness direction. That is, only by attaching the anisotropic electrically conductive adhesive film 3 and then, by heating, it is possible to electrically connect the through electrodes 2 to each other. Therefore, it has excellent productivity.

Specifically, in order to electrically connect the through electrodes 2 to each other, for example, after the semiconductor substrate 1 is laminated, it is also considered that the semiconductor substrate 1 is drilled and filled with a metal.

On the other hand, according to the method for producing the semiconductor device 9, only by attaching the anisotropic electrically conductive adhesive film 3, and then, by heating, it is possible to electrically connect the through electrodes 2 to each other. Therefore, it has the excellent productivity.

Further, in the above-described description, in the fourth step, the first laminate 5 is not heated. However, in the fourth step, the first laminate 5 may be also heated. In the fourth step, when the first laminate 5 is heated, the heating temperature is, for example, below 100° C., preferably 80° C. or less, and for example, 40° C. or more.

That is, in the fourth step, the first laminate 5 is laminated with heating below 100° C., thereby producing the second laminate 6. Or, the first laminate 5 is laminated without heating, thereby producing the second laminate 6.

Then, in the fifth step, by collectively heating the second laminate 6 consisting of the plurality of first laminates 5, the solder particles 10 are melted, thereby forming the columnar solder portion 7. In addition, in the sixth step, by collectively heating the second laminate 6, the curable resin is cured.

That is, in this method, preferably, the fifth step and the sixth step are not repeated whenever one layer of the first laminate 5 is laminated. Instead, the fifth step and the sixth step are carried out at once after the plurality of first laminates 5 are laminated. In other words, in this method, the fifth step and the sixth step are not carried out for each first laminate 5. Instead, the fifth step and the sixth step are carried out at once with respect to the second laminate 6 consisting of the plurality of first laminates 5. Therefore, it has the excellent productivity.

Preferably, from the viewpoint of further improving the productivity, in the fourth step, the first laminate 5 is laminated without heating, thereby producing the second laminate 6.

The semiconductor device 9 includes the curing resin layer 8 disposed between the semiconductor substrates 1 adjacent to each other in the thickness direction. Therefore, it is possible to reliably seal the semiconductor element in the semiconductor substrate 1. As a result, it has the excellent reliability. Further, in the semiconductor device 9, the columnar solder portion 7 passes through the curing resin so as to electrically connect the through electrodes 2 of the semiconductor substrates 1 adjacent to each other in the thickness direction. Therefore, it is possible to reliably electrically connect the through electrodes 2 to each other.

### Modified Examples

In each modified example, the same reference numerals are provided for members and steps corresponding to each of those in one embodiment, and their detailed description is omitted. Further, each modified example can achieve the same function and effect as that of one embodiment unless otherwise specified. Furthermore, one embodiment and each modified example can be appropriately used in combination.

In the above-described description, in the seventh step, the dicing tape 20 is prepared, and the first laminate 5 is disposed on one surface in the thickness direction of the dicing tape 20. Alternatively, in the first step, the dicing tape 20 is prepared in advance, and it is also possible to dispose the semiconductor substrate 1 on the dicing tape 20. Specifically, the semiconductor substrate 1 is disposed on one surface in the thickness direction of the dicing tape 20 (ref: broken line of FIG. 1).

In the above-described description, in the seventh step, the dicing tape 20 is prepared, and the first laminate 5 is disposed on one surface in the thickness direction of the dicing tape 20. Alternatively, in the second step, the dicing tape 20 is prepared in advance, and it is also possible to dispose the anisotropic electrically conductive adhesive film 3 on the dicing tape 20.

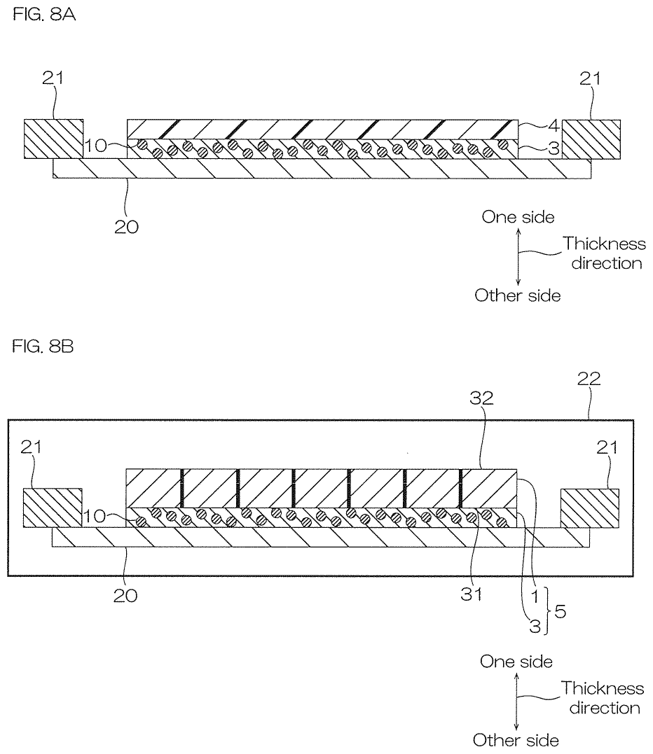

Specifically, as shown in FIG. 8A, the anisotropic electrically conductive adhesive film 3 is disposed on one surface in the thickness direction of the dicing tape 20.

Then, in such a case, as shown in FIG. 8B, in the third step, the anisotropic electrically conductive adhesive film 3 is attached to the surface (other surface in the thickness direction) of the semiconductor substrate 1, thereby producing the first laminate 5.

Also, in the above-described description, in order to prepare the plurality of first laminates 5, the first laminates 5 are singulated. Alternatively, it is also possible to prepare the plurality of first laminates 5 by carrying out the first step to the third step multiple times without singulating the first laminates 5.

Also, in the above-described description, in the fifth step and the sixth step, the second laminate 6 is heated using the pressure oven 25. However, a heating method is not limited to this. It is also possible to use, for example, reflow heating and hot plates.

In addition, in the above-described description, the fifth step and the sixth step are carried out separately (that is, after the fifth step is carried out, the sixth step is carried out). Alternatively, it can also carry out as a series of steps without separating the fifth step from the sixth step.

### EXAMPLES

Next, the present invention is further described based on Examples below. The present invention is however not limited by Examples. The specific numerical values in mixing ratio (content ratio), property value, and parameter used in Examples can be replaced with upper limit values (numerical values defined as “or less” or “below”) or lower limit values (numerical values defined as “or more” or “above”) of corresponding numerical values in mixing ratio (content ratio), property value, and parameter described in the above-described “DESCRIPTION OF EMBODIMENTS”.

### <Production of Semiconductor Device>

### Example 1

### First Step

As shown in FIG. 1, the semiconductor substrate 1 was prepared. The semiconductor substrate 1 had the cylindrical through electrode 2 having a diameter of 15 μm and a thickness of 1 μm, and a distance between the through electrodes 2 adjacent to each other was 15 μm.

### Second Step

As shown in FIG. 2, the anisotropic electrically conductive adhesive film 2 was prepared.

The anisotropic electrically conductive adhesive film composition was prepared in order to prepare the anisotropic electrically conductive adhesive film 2.

Specifically, as the thermosetting resin, 50 parts by mass of jER828 (bisphenol A-type epoxy resin, manufactured by Mitsubishi Chemical Corporation); 50 parts by mass of jER1007 (bisphenol A-type epoxy resin, softening point: 128° C., manufactured by Mitsubishi Chemical Corporation); 150 parts by mass of the solder particles 10 (alloy of 96.5% by mass of Sn, 3.0% by mass of Ag, and 0.5% by mass of Cu, melting point of 217 to 219° C., spherical shape, particle size D50 of 3 μm, oxygen concentration of 1100 ppm); and as the flux, 15 parts by mass of the malic acid were added to methyl ethyl ketone (MEK) to be mixed, thereby preparing the anisotropic electrically conductive adhesive film composition (solid concentration of 50% by mass).

Next, the anisotropic electrically conductive adhesive film composition was applied onto the release liner 4 to form a coating film, and then, the coating film was dried at 60° C. for 5 minutes. Thus, the anisotropic electrically conductive adhesive film 3 was prepared.

### Third Step

As shown in FIG. 3, the anisotropic electrically conductive adhesive film 3 was attached to the surface (one surface in the thickness direction) of the semiconductor substrate 1, thereby producing the first laminate 5.

### Seventh Step

As shown in FIGS. 4A to 4C, the first laminate 5 was singulated, thereby preparing the plurality of first laminates 5.

### Fourth Step

As shown in FIG. 5, the plurality of first laminates 5 were laminated, thereby producing the second laminate 6.

### Fifth Step

As shown in FIG. 6, the second laminate 6 was heated and the solder particles 10 were melted, thereby forming the columnar solder portion 7 so as to electrically connect the through electrodes 2 of the semiconductor substrates 1 adjacent to each other in the thickness direction. The above-described heating was carried out using the vacuum pressurizing reflow device at the temperature rising rate of 100° C./min until the maximum temperature of 250° C. at the pressure of 0.4 MPa. The heating time was 5 minutes.

### Sixth Step

The second laminate 6 was heated, thereby curing the curable resin. The above-described heating was carried out using the vacuum pressurizing reflow device at the temperature rising rate of 100° C./min until the maximum temperature of 200° C. at the pressure of 0.4 MPa. The heating time was 60 minutes. As described above, the semiconductor device 9 was produced.

### Example 2 and Example 3

A semiconductor device was produced based on the same process as in Example 1. The maximum temperature, the temperature rising rate, and the heating time in the fifth step and the sixth step were changed in accordance with Table 1.

### Evaluation

### (Electrical Conductivity)

As for each of the semiconductor devices of Examples, after the semiconductor device was polished to a portion where connection was formed by using the anisotropic electrically conductive adhesive film to confirm a cross section of the connection portion, the columnar solder portion was observed with an SEM. Electrical conduction of a counter electrode was evaluated based on the following criteria.

### (Criteria)

∘: the connection of the upper and lower electrodes by the columnar solder portion was observed.
x: the connection of the upper and lower electrodes by the columnar solder portion was not observed.

### (Sealing Properties)

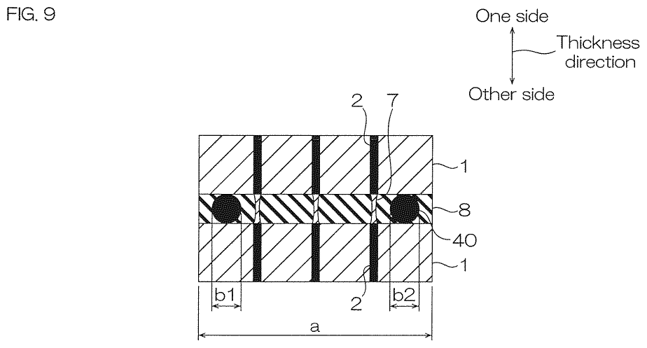

As for each of the semiconductor devices of Examples, after the semiconductor device was polished to the portion where the connection was formed by using the anisotropic electrically conductive adhesive film to confirm the cross section of the connection portion, voids of the curing resin layer (film portion) were observed. Specifically, as shown in FIG. 9, a void ratio was calculated as a ratio (void ratio=(b1+b2)/a×100(%)) of lengths (b1, b2) where each void 40 was located with respect to a length a of the semiconductor substrate 1. Sealing properties were evaluated based on the following criteria.

### (Criteria)

∘: the void ratio was 30% or less.
x: the void ratio was above 30%.

TABLE 1

| Ex. No. | | | | Ex. 1 | Ex. 2 | Ex. 3 |
|---|---|---|---|---|---|---|
| Anisotropic | Anisotropic | Curable Resin | jER1007 | 50 | 50 | 50 |
| | Electrically | | (softening point: 128° C.) | | | |
| Electrically | Conductive | | jER828 | 50 | 50 | 50 |
| Conductive | Adhesive | Solder Particle | SnAgCu | 150 | — | 150 |
| | | | (melting point: 217 to 219° C.) | | | |
| Adhesive | Film | | SnBi (melting point: 139° C.) | — | 150 | — |
| Film | Composition | Flux | Malic Acid | 15 | 15 | 15 |
| | | (solid content) | | | | |

| | Film Thickness (um) | | 5 | 5 | 5 |
|---|---|---|---|---|---|
| Process | Fifth Step | Device | Vacuum | Vacuum | Vacuum |
| | | | Pressurizing | Pressurizing | Pressurizing |
| | | | Reflow | Reflow | Rcflow |
| | | | Device | Device | Device |
| | | Maximum Temperature (° C.) | 250 | 170 | 250 |
| | | Temperature Rising Rate (° C./min) | 100 | 100 | 100 |
| | | Heating Time (min) | 5 | 5 | 5 |
| | | Pressure (Mpa) | 0.4 | 0.4 | 0.4 |
| | Sixth Step | Device | Vacuum | Vacuum | Vacuum |

| | Pressurizing | Pressurizing | Pressurizing |
|---|---|---|---|
| | Reflow | Reflow | Reflow |
| | Device | Device | Device |
| Maximum Temperature (° C.) | 200 | 150 | 200 |
| Temperature Rising Rate (° C./min) | 100 | 100 | 3 |
| Heating Time (min) | 60 | 120 | 60 |
| Pressure (Mpa) | 0.4 | 0.4 | 0.4 |

| | | | | |
|---|---|---|---|---|
| Reliability | Electrical Conductivity | ◯ | ◯ | ◯ |
| | Sealing Properties | ◯ | ◯ | ◯ |

While the illustrative embodiments of the present invention are provided in the above description, such is for illustrative purpose only and it is not to be construed as limiting the scope of the present invention. Modification and variation of the present invention that will be obvious to those skilled in the art is to be covered by the following claims.

### INDUSTRIAL APPLICATION

The semiconductor device and the method for producing a semiconductor device of the present invention can be preferably used in, for example, DRAM.

### DESCRIPTION OF REFERENCE NUMERALS

1 Semiconductor substrate
2 Through electrode
3 Anisotropic electrically conductive adhesive film
5 First laminate
5′ Singulated first laminates
6 Second laminate
7 Columnar solder portion
8 Curing resin layer
10 Solder particle
20 Dicing tape
25 Pressure oven

1. A semiconductor device comprising:
a plurality of semiconductor substrates disposed in a thickness direction each including a through electrode passing through in the thickness direction, and
a curing resin layer disposed between the semiconductor substrates adjacent to each other in the thickness direction, wherein
the curing resin layer includes a curing resin and a columnar solder portion embedded in the curing resin, and
the columnar solder portion passes through the curing resin so as to electrically connect the through electrodes of the semiconductor substrates adjacent to each other in the thickness direction.

2. A method for producing a semiconductor device comprising:
a first step of preparing a semiconductor substrate including a through electrode passing through in a thickness direction;
a second step of preparing an anisotropic electrically conductive adhesive film including a solder particle and a curable resin;
a third step of producing a first laminate by attaching the anisotropic electrically conductive adhesive film on a surface of the semiconductor substrate;
a fourth step of producing a second laminate by laminating the plurality of first laminates;
a fifth step of forming a columnar solder portion so as to electrically connect the through electrodes of the semiconductor substrates adjacent to each other in the thickness direction by heating the second laminate and melting the solder particle; and
a sixth step of heating the second laminate and curing the curable resin.

3. The method for producing a semiconductor device according to claim 2, wherein
after the third step and before the fourth step, a seventh step of singulating the first laminates is provided, and
in the fourth step, the plurality of singulated first laminates are laminated to produce a second laminate.

4. The method for producing a semiconductor device according to claim 3, wherein
the seventh step includes a step of preparing a dicing tape extendable in a plane direction perpendicular to the thickness direction,
a step of disposing the first laminate on one surface in the thickness direction of the dicing tape, and
a step of singulating the first laminate by extending the dicing tape in the plane direction.

5. The method for producing a semiconductor device according to claim 3, wherein
in the first step, the semiconductor substrate is disposed on a dicing tape extendable in a plane direction perpendicular to the thickness direction.

6. The method for producing a semiconductor device according to claim 3, wherein
in the second step, the anisotropic electrically conductive adhesive film is disposed on a dicing tape extendable in a plane direction perpendicular to the thickness direction.

7. The method for producing a semiconductor device according to claim 2, wherein
in the fourth step,
by laminating the first laminate with heating below 100° C., the second laminate is produced, or
by laminating the first laminate without heating, the second laminate is produced, and
in the fifth step, the second laminate consisting of the plurality of first laminates is collectively heated.

8. The method for producing a semiconductor device according to claim 7, wherein
in the fourth step, by laminating the first laminate without heating, the second laminate is produced, and in the fifth step, the second laminate consisting of the plurality of first laminates is collectively heated.

9. The method for producing a semiconductor device according to claim 2, wherein
in the fifth step, the heating is carried out so that the maximum temperature is higher than a softening point of the curable resin.

10. The method for producing a semiconductor device according to claim 9, wherein
the maximum temperature is 150° C. or more and 260° C. or less.

11. The method for producing a semiconductor device according to claim 2, wherein
in the fifth step, the heating is carried out in a pressure oven.

12. The method for producing a semiconductor device according to claim 2, wherein
in the sixth step, the heating is carried out so that the maximum temperature is 100° C. or more and 260° C. or less.

13. The method for producing a semiconductor device according to claim 2, wherein
the heating in the sixth step is carried out in a pressure oven.
